(19) United States
(12) Patent Application Publication
(10) Pub. No.: US 2019/0113953 A1
(43) Pub. Date: Apr. 18, 2019

(54) A SEAL FOR AN ELECTRONIC DEVICE

(71) Applicant: HEWLETT-PACKARD DEVELOPMENT COMPANY, L.P., HOUSTON, TX (US)

(72) Inventor: TIMOTHY SUTHERLAND, SAN DIEGO, CA (US)

(21) Appl. No.: 16/091,015

(22) PCT Filed: Jun. 28, 2016
(86) PCT No.: PCT/US2016/039867

§ 371 Date: Oct. 3, 2018

(51) Int. Cl. G06F 1/16; H01R 13/52; H01R 43/24; H05K 5/00; H01H 9/02

(52) U.S. Cl. CPC G06F 1/1656; H01R 13/5202; G06F 1/1626; H05K 5/0034; H01H 9/02; H01R 43/24

(57) ABSTRACT

In some examples, an electronic device includes an outer housing, support structures for electronic components of the electronic device, and a seal that extends along a circumference on an inner surface of the outer housing, the seal engaged to the inner surface of the outer housing and engaged to the support structures for the electronic components. The seal is deflectable by the support structures upon engagement of the seal with the support structures when the support structures are received in an inner chamber defined by the outer housing, and the seal is arranged to enhance sealing engagement with the support structures responsive to pressure applied by a liquid that has penetrated a portion of the outer housing.

### BACKGROUND

An electronic device includes an outer housing and various electronic components contained inside the outer housing. Openings can be provided in the outer housing for a display panel, buttons, connectors, and/or other features of the electronic device.

### BRIEF DESCRIPTION OF THE DRAWINGS

Some implementations of the present disclosure are described with respect to the following figures.

FIG. 1A is a top view of a portion of an electronic device including a sealing arrangement according to some examples.

FIG. 1B is a cross-sectional view of a portion of an electronic device including a sealing arrangement according to some examples.

FIG. 2A is a top view of a portion of an electronic device including a sealing arrangement according to further examples.

FIG. 2B is a cross-sectional view of a portion of an electronic device including a sealing arrangement according to further examples.

FIG. 3 is a cut-away view of a portion of an electronic device to illustrate a connector assembly and a sealing arrangement for the connector assembly according to some examples.

FIG. 4A is a perspective view of an exploded portion of an electronic device to illustrate a connector assembly according to further examples.

FIG. 4B is a cross-sectional view of a portion of an electronic device that includes the connector assembly of FIG. 4A and a sealing arrangement for the connector assembly of FIG. 4A, according to further examples.

FIG. 5A is a cut-away view of a portion of an electronic device to illustrate a button assembly and a sealing arrangement for the button assembly, according to some examples.

FIG. 5B is a perspective view of a button assembly according to some examples.

FIG. 6 is a simplified diagram of a portion of a housing assembly according to some examples.

FIG. 7 is a flow diagram of a process of forming a housing assembly according to some examples.

### DETAILED DESCRIPTION

Openings can be formed in an outer housing of an electronic device to mount various features, such as a display panel, a connector, a user-actuatable button, a keyboard, a keypad, or any other feature. The presence of the openings can form liquid ingress paths in the outer housing, which can allow a liquid such as water to pass into an inner region of the electronic device. A user of the electronic device may accidentally drop the electronic device into a pool of water. Alternatively, a user may accidentally spill liquid onto the electronic device. Any liquid entering the electronic device's inner region can damage electronic components located in the inner region.

Examples of electronic devices can include any of the following: a smartphone, a tablet computer, a notebook computer, a game appliance, a wearable device (e.g., a smartwatch, smart eyeglasses, etc.), or any other type of electronic device.

In some examples, to protect electronic components from damage due to ingress of liquids, various seals can be provided to protect certain parts of the electronic device. Such seals may be complex in nature or may not comprehensively protect the entire electronic device.

In accordance with some implementations of the present disclosure, a primary seal can be provided inside the outer housing of the electronic device to prevent liquid that has entered through liquid ingress paths in the outer housing from passing into an inner region of the electronic device, such that electronic components inside the inner region are protected from the liquid. An “inner region” of an electronic device where electronic components can refer to any portion of an inner chamber within the outer housing of the electronic device that is to be protected from penetration of a liquid. Examples of electronic components that can be damaged by liquid can include any or some combination of the following: a processor, a memory device, a storage device, a display panel, a battery, an input/output (I/O) device, and so forth.

The primary seal can be a unitary seal that extends along a circumference on an inner surface of the outer housing. A unitary seal can refer to a seal without any breaks in the seal. In some examples, the circumference along which the primary seal extends can be generally rectangular in shape, with deviations from such rectangular shape at respective locations to accommodate connectors, buttons, or other features of the electronic device. In other examples, the primary seal can extend along a circumference of a different shape.

By arranging the primary seal along a circumference on the inner surface of the outer housing of the electronic device, a protective barrier can be set up along a perimeter of the electronic device. This primary seal is the main seal that prevents ingress of a liquid that has entered through ingress liquid paths of the electronic device. It is noted that additional seals can be provided to supplement the primary seal at certain parts of the electronic device, as discussed further below. For example, such additional seals can be provided for a connector assembly and/or for a button assembly of the electronic device, to further prevent liquid that has penetrated into the connector assembly or button assembly from entering into the inner region of the electronic device.

In some examples, the primary seal is formed of a material that is deflectable by support structures inside the electronic device when the support structures are mounted inside the outer housing of the electronic device. A “support structure” can refer to any structure in the electronic device that is used to support a component (or multiple components) inside the electronic device. A support structure can be separate from the outer housing, can be attached to the outer housing, or can be part of the outer housing. A support structure can be formed of a material that includes a metal, a plastic, or any other rigid material.

An example of a material that is deflectable is silicone. More generally, the primary seal can be formed of a polymer, or any other type of material that when pressed up against or otherwise engaged with another structure forms a liquid seal.

The deflection of the primary seal by a support structure provides for a sealing engagement between the primary seal and the support structure, such that a liquid cannot pass through the interface between the primary seal and the support structure.

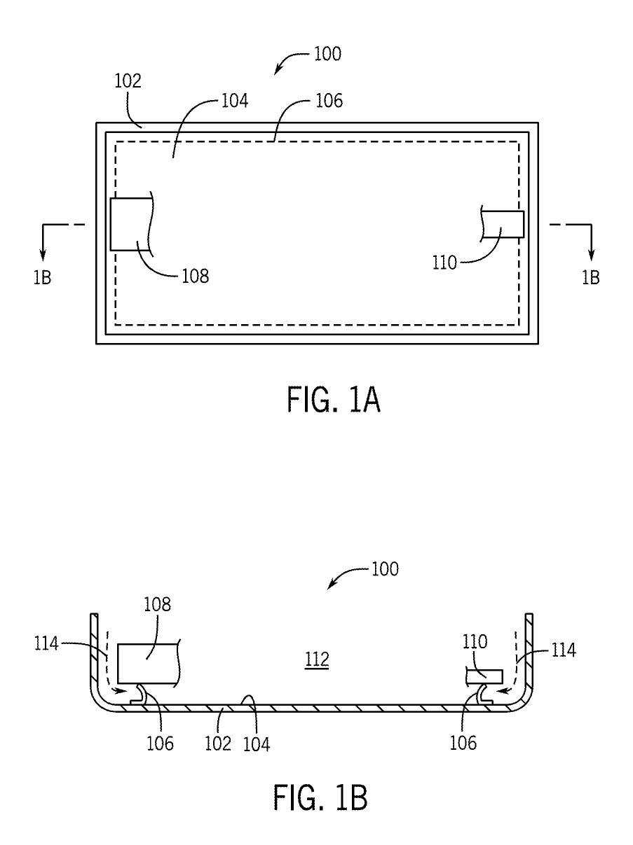

FIGS. 1A and 1B show portions of an electronic device 100 according to some examples. FIG. 1A is a top view of the electronic device 100, while FIG. 1B is a cross-sectional side view of the electronic device 100 along section 1B-1B shown in FIG. 1A.

The electronic device 100 includes an outer housing 102, which can be formed of any rigid material, such as metal, plastic, and so forth. Note that the term “housing” can refer to a unitary housing structure, or multiple housing structures that are attached together. The outer housing 102 has an inner surface 104, along which a primary seal 106 is provided. The primary seal 106 extends along a circumference on the inner surface 104 of the outer housing 102. The circumference defines a perimeter just inside the outer side edges of the outer housing 102. The primary seal 106 provides a barrier where liquid from outside the primary seal 106 is unable to penetrate into an inner region of the electronic device 100 that is within the circumference along which the seal 106 extends.

Although just one primary seal 106 is shown in FIGS. 1A and 1B, it is noted that in other examples, multiple primary seals can be provided on the inner surface 104 of the outer housing 102, where the multiple primary seals can extend along respective circumferences.

The electronic device 100 includes support structures 108 and 110, which can be used to support various components in the electronic device 100, such as a display panel, a connector assembly, a button assembly, a battery, a printed circuit board, a processor, a memory device, or any other component. Although two support structures 108 and 110 are shown in FIGS. 1A and 1B, it is noted that in other examples, a different number of support structures can be included inside the electronic device 100.

As depicted in FIG. 1B, a lower surface of the primary seal 106 is engaged to the inner surface 104 of the outer housing 102. In some examples, the primary seal 106 can be overmolded onto the inner surface 104 of the outer housing 102. The overmolding process can involve first forming the outer housing 102 to a target shape, and then injection molding the primary seal 106 onto the inner surface 104 of the outer housing 102 to form a single part. In other examples, the primary seal 106 can be attached to the inner surface 104 of the outer housing 102 using a different technique, such as by using an adhesive or the like.

When the support structures 108 and 110 are mounted into an inner chamber 112 inside the outer housing 102, the support structures 108 and 110 press downwardly onto the primary seal 106 to deflect the upper portion of the primary seal 106. The deflection of the upper portion of the primary seal 106 allows for a sealing engagement to be formed between the primary seal 106 and the support structures 108 and 110. The primary seal 106 is deflectable by the support structures 108 and 110 upon engagement of the primary seal 106 with the support structures 108 and 110 when the support structures 108 and 110 are received in an inner chamber 112 defined by the outer housing 102.

The sealing engagement between the primary seal 106 and the support structures 108 and 110 can further be enhanced when pressure is applied by a liquid that has penetrated into a portion of the outer housing 102 and has pushed up against the primary seal 106, as indicated by arrows 114.

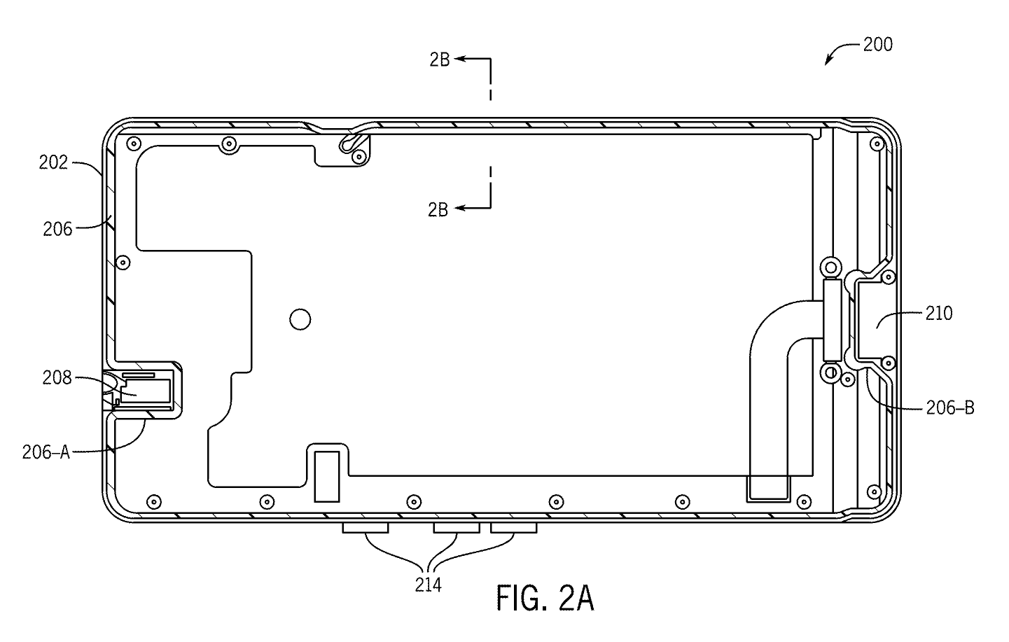

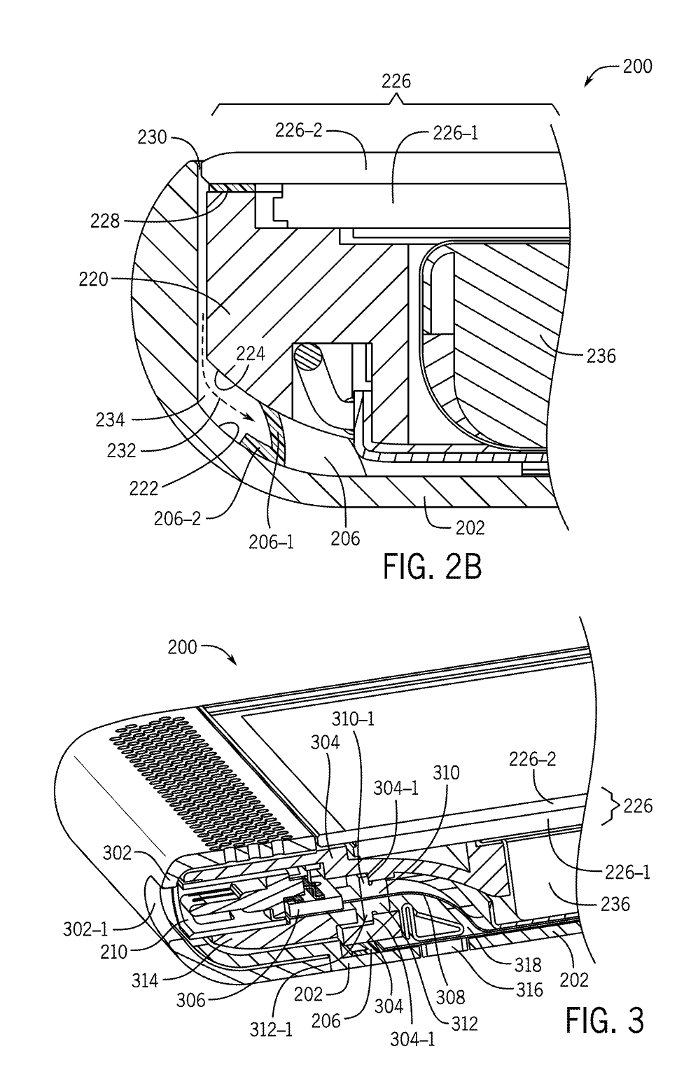

FIG. 2A is a top view of a portion of an electronic device 200 according to further examples. The electronic device 200 includes an outer housing 202, and a primary seal 206 that extends along a circumference on an inner surface of the outer housing 202. In FIG. 2A, various components that would be placed in an inner chamber defined by the housing 202 are omitted to allow the primary seal 206 to be visible along its entire circumference.

The circumference along which the primary seal 206 extends is generally rectangular in shape, but has a first deflected portion 206-A to accommodate a first connector assembly 208, and a second deflected portion 206-B to accommodate a second connector assembly 210. The connector assembly 208 can be a first type of connector assembly, while the connector assembly 210 can be a second, different type of connector assembly. For example, the connector assembly 208 can include a High Speed J (HSJ) connector that can mate with a corresponding connector to perform audio and video communications. The connector assembly 210 can include a Universal Serial Bus (USB) connector to mate with a corresponding connector to perform USB communications. In other examples, other types of connector assemblies can be employed. Also, although two connector assemblies 208 and 210 are shown in FIG. 2A, it is noted that in other examples, the electronic device 200 can include just one connector assembly or more than two connector assemblies.

A connector assembly can also be referred to as a “communication connector assembly,” since it is used to allow communications between the electronic device and an external device.

The electronic device 200 also includes user-actuatable buttons 214 that can be actuated by a user, such as by pressing down on each button 214. The buttons 214 protrude from a side of the outer housing 202. Although three buttons 214 are shown, it is noted that in other examples, a different number of buttons can be provided. Also, buttons can additionally or alternatively be provided on other parts of the outer housing 202.

FIG. 2B shows a cross-sectional view along section 2B-2B of the electronic device 200 of FIG. 2A. In the FIG. 2B view, various components that are received in the inner chamber defined by the outer housing 202 are shown. In FIG. 2B, a support structure 220 is mounted in an inner chamber defined by the inner surface 222 of the outer housing 202. As shown in FIG. 2B, the bottom surface of a lower portion 206-2 of the primary seal 206 is engaged to the inner surface 222 of the outer housing 202, such as by using an overmolding process or by using another bonding technique. The support structure 220 when received in the inner chamber of the outer housing 202 presses against the primary seal 206 to deflect an upper portion 206-1 of the primary seal 206 downwardly, to provide a sealing engagement between the seal upper portion 206-1 and a lower surface 224 of the support structure 220.

The support structure 220 supports a display assembly 226 that includes a display panel 226-1 and a display cover 226-2 that lies over an upper surface of the display panel 226-1 to protect the upper surface of the display panel 226-1. The display cover 226-2 can be formed of a glass, a transparent plastic, or any other material that is transparent. The display panel 226-1 can include a liquid crystal display (LCD) panel, an organic light-emitting diode (OLED) display panel, and so forth.

An adhesive seal 228 is sandwiched between an end portion of the display cover 226-2 and an upper surface of the support structure 220. The adhesive seal 228 is adhered to the respective surfaces of the display cover 226-2 and the support structure 220, to form a seal between the display cover 226-2 and the support structure 220. The adhesive seal 228 can be formed of a polymer or any other type of material that can provide a seal against a liquid.

A gap 230 exists between the inner surface 222 of the outer housing 202 and several components inside the inner chamber of the outer housing 202, including the display cover 226-2 and the support structure 220. The gap 230 provides a liquid ingress path that allows a liquid outside the electronic device 200 to enter through the gap 230 into a portion of the inner chamber of the outer housing 202. As shown in FIG. 2B, the liquid that enters through the gap 230 can be communicated along path 232 to a chamber 232, where the liquid can contact the primary seal 206. The adhesive seal 228 prevents liquid that has entered through the gap 230 from passing between the display cover 226-2 and the support structure 220.

As further shown in FIG. 2B, the seal upper portion 206-1 and the seal lower portion 206-2 of the primary seal 206 are arranged such that they have an acute angle with respect to each other when facing the chamber 234 into which a liquid can pass. Thus, the liquid that has flowed into the chamber 234 can apply a pressure against the seal 206. This pressure applied by the liquid further pushes the seal upper portion 206-1 against the lower surface 224 of the support structure 220, to enhance the sealing engagement between the seal 206 and the support structure 220. Thus, presence of liquid in the chamber 234 actually enhances the seal provided by the primary seal 206, which further provides protection against liquid entering into an inner region of the electronic device 200 past the primary seal 206.

As further shown in FIG. 2B, a battery 236 is also present inside the inner chamber of the outer housing 202. By using the primary seal 206 and the adhesive seal 228 as shown in FIG. 2B, the display panel 226-1 and the battery 236 (along with other electronic components inside the electronic device 200) are protected against entry of a liquid.

FIG. 3 is a cut-away view of a portion of the electronic device 200 to illustrate the connector assembly 210, according to some examples. In examples according to FIG. 3, a cap 302 is mounted over the outer housing 202 of the electronic device 200, as well as over a support structure 304 for the connector assembly 210. The cover 302 has an opening 302-1 to allow for a mating connector to engage with the connector assembly 210 that is positioned adjacent the opening 302-1.

The support structure 304 retains the connector assembly 210 in position, as well as also provides support for the display assembly 226. The cap 302 is mounted over the external surface of the support structure 304 as well as the outer surface of the outer housing 202.

The connector assembly 210 includes a connector circuit board 306, which receives electrical signals from electrical contact pins of the connector assembly 210. The connector assembly 210 also includes a retaining bracket 314. The retaining bracket sits on the inner surface of the external housing 202.

The circuit board 306 of the connector assembly 210 is electrically connected to a communication cable 308, which can be a flex cable in some examples. The cable 308 includes electrical conductors to carry electrical signals between the connector assembly 210 and another electronic component (e.g., a main circuit board) in the electronic device 200. Connector seals 310 and 312 are engaged to respective surfaces of the cable 308. In some examples, the seals 310 and 312 can be formed with the cable 308 as a single structure by using an overmolding process. In other examples, the seals 310 and 312 can be bonded to the seal 308 using a different technique.

The support structure 304 includes an engagement portion 304-1 to engage respective engagement portions 310-1 and 312-1 of the seals 310 and 312. This engagement between the seals 310, 312 and the support structure 304 provides for a sealing engagement between the seals 310, 312 and the support structure 304.

Although not shown, an adhesive seal can also be provided between an end portion of the display cover 226-2 and the support structure 304, similar to the adhesive seal 228 shown in FIG. 2B.

If the electronic device 200 is exposed to liquid, liquid can potentially enter through the opening 302-1 of the cap 302 and into the inner chamber of the connector assembly 210. Liquid that has entered into the inner chamber of the connector assembly 210 is prevented from passing into an inner region of the electronic device 200 by the seals 310 and 312.

As further shown in FIG. 3, the support structure 304 is engaged with the primary seal 206, by pressing down on the primary seal 206. Liquid that enters through the opening 302-1 of the cap 302 can also potentially pass through a gap between the retaining bracket 314 of the connector assembly 210 and the inner surface of the outer housing 202. This liquid can be communicated to the primary seal 206. Any pressure applied by this liquid pushes the primary seal 206 into further engagement with the support structure 304, which enhances the sealing engagement between the primary seal 206 and the support structure 304. The primary seal 206 thus acts to prevent the liquid that has entered into any gap between the retaining bracket 314 and the outer housing 202 from passing into the inner region of the electronic device 200.

In examples according to FIG. 3, a contact pin 316 is also provided in the outer housing 202. The contact pin 316 can be used to make electrical contact with an external object. The presence of the contact pin 316 provides a possible liquid ingress path in any gap between the outer housing 202 and the contact pin 316. An adhesive seal 318 is provided over the area of the inner surface of the outer housing 202 to cover the contact pin 316, such that liquid is prevented from entering through the gap between the contact pin 316 and the outer housing 202 into the inner region of the electronic device 200.

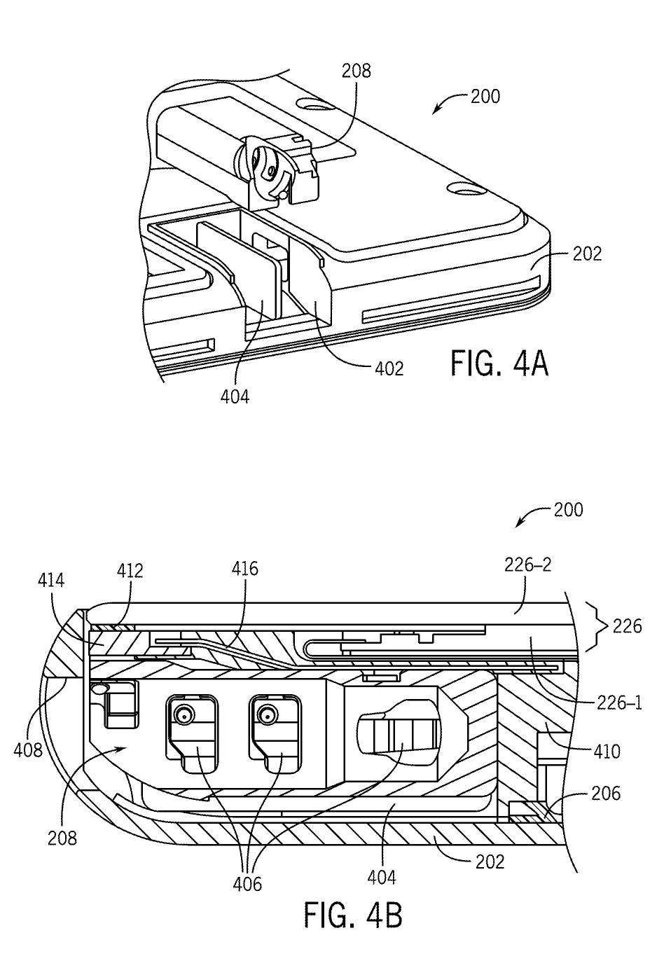

FIGS. 4A and 4B depict a portion of the electronic device 200 that includes the connector assembly 208. The connector assembly 208 can be received in a receptacle 402 defined in the outer housing 202 of the electronic device 200. As further shown in FIG. 4A, a connector circuit board 404 is provided, where the connector circuit board 404 is electrically contacted to contact pins 406 of the connector assembly 208. An opening 408 is formed in the outer housing 202, to allow a mating connector to be inserted into the connector assembly 208 to contact the contact pins 406.

A support structure 410 is provided in the electronic device 200 to retain the connector assembly 208 and also to support the display assembly 226. The support structure 410 engages the primary seal 206, to provide a seal between the support structure 410 and the outer housing 202. Thus, any liquid that enters into the inner chamber of the electronic device 200 between the connector assembly 208 and the inner surface of the outer housing 202 is stopped by the primary seal 206.

An adhesive seal 412 can also be provided between the display cover 226-2 of the display assembly 226 and an upper structure 414 of the connector assembly 208, to provide a seal between the display cover 226-2 and the upper structure 414.

As further shown in FIG. 4B, a cover plate 416 for the connector assembly 208 is adhesively attached to the support structure 410. The adhesive attachment between the cover plate 416 and the support structure 410 provides a sealing engagement to prevent liquid from entering between the cover plate 416 and the support structure 410.

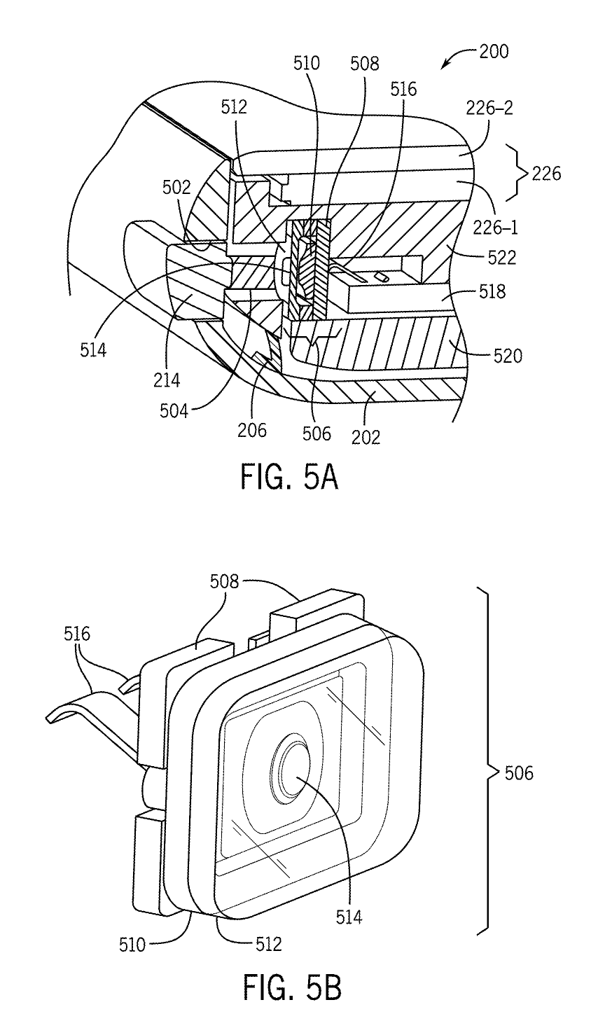

FIG. 5A shows a portion of the electronic device 200 that includes a button assembly including a button 214, which is located in an opening 502 formed in the outer housing 202. A portion of the button 214 protrudes above the outer surface of the outer housing 202, to allow a user to press against the button 214.

The button assembly further includes a plunger 504 that is attached to the button 214, such that when the user presses against the button 214, the plunger 504 moves by the corresponding distance against a dome switch 506 arranged in a pocket inside the electronic device. A prospective view of the dome switch 506 is shown in FIG. 5B. The dome switch 506 has a circuit board 508, a support layer 510 which can be formed of a plastic or other material that is located between the circuit board 508, and a compressible layer 512 (which is a liquid seal), which can be overmolded onto the support layer 510 in some examples. The compressible layer 512 can be formed of a silicone or other similar material that can be compressed in response to a force applied by the plunger 504 on the button 214. A switch contact portion 514 is covered by the compressible layer 512. When the plunger 504 pushes against the dome switch 506 to compress the compressible layer 512, the plunger 504 pushes against the switch contact portion 514 to activate the dome switch 506. Electrical spring contacts 516 are connected to the circuit board 508. The electrical spring contacts 516 extend from the circuit board 508 of the dome switch 506, to a main circuit board 518 of the electronic device 200. The main circuit board 518 is located on a support substrate 520.

A support structure 522 is used to provide support for the dome switch 506. In addition, a lower surface of the support structure 522 engages against the primary seal 206. Any liquid that enters through the opening 502 of the outer housing 202 is blocked from entry by the primary seal 206 between the support structure 522 and the inner surface of the outer housing 202.

In addition, the engagement between the compressible layer 512 of the dome switch 506 and a respective surface of the support structure 522 is a sealing engagement to prevent liquid ingress pass the dome switch 506 into the inner region of the electronic device 200.

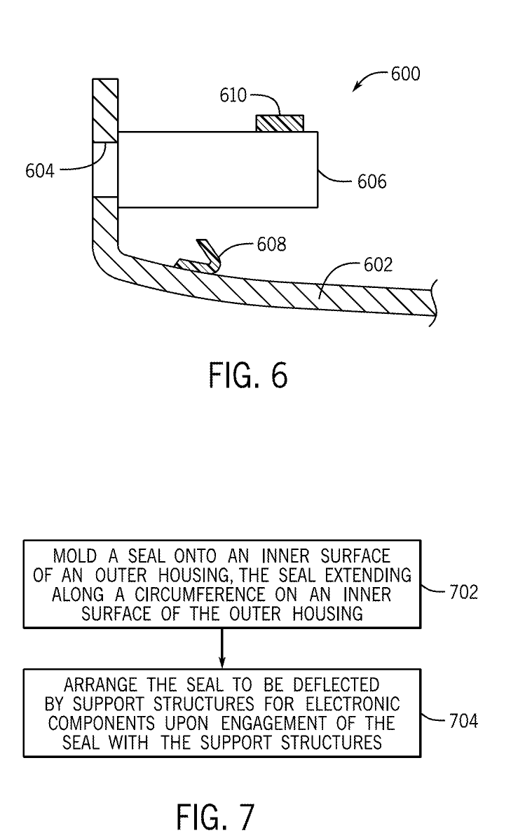

FIG. 6 is a schematic diagram of a housing assembly 600 for an electronic device, such as the electronic device 100 or 200 discussed above. The housing assembly 600 includes an outer housing 602, an opening 604 in the outer housing 602 for a connector assembly 606 of the electronic device. In addition, the housing assembly 600 includes a first seal 608, which can be the primary seal 206 discussed above. Additionally, a second seal 610, which can be the seals 310, 312 of FIG. 3A, or the seal 412 of FIG. 4B, or the adhesive seal between the cover plate 416 and the support structure 410 of FIG. 4B, is provided to engage a component of the connector assembly 606 to prevent liquid that has entered the connector assembly 606 from passing to an inner region of the electronic device.

FIG. 7 is a flow diagram of a method of forming a housing assembly for an electronic device. The process of FIG. 7 includes molding (at 702) a seal onto an inner surface of an outer housing of the electronic device, the seal extending along a circumference on an inner surface of the outer housing. The process further includes arranging (at 704) the seal to be deflected by support structures for electronic components upon engagement of the seal with the support structures when the support structures are received in an inner chamber defined by the outer housing, where the seal is arranged to enhance a sealing engagement with the support structures responsive to pressure applied by a liquid that has penetrated a portion of the outer housing.

In the foregoing description, numerous details are set forth to provide an understanding of the subject disclosed herein. However, implementations may be practiced without some of these details. Other implementations may include modifications and variations from the details discussed above. It is intended that the appended claims cover such modifications and variations.

What is claimed is:

1. An electronic device comprising:
an outer housing;
support structures for electronic components of the electronic device;
a seal that extends along a circumference on an inner surface of the outer housing, the seal engaged to the inner surface of the outer housing and engaged to the support structures for the electronic components,
the seal deflectable by the support structures upon engagement of the seal with the support structures when the support structures are received in an inner chamber defined by the outer housing, and the seal arranged to enhance sealing engagement with the support structures responsive to pressure applied by a liquid that has penetrated a portion of the outer housing.

2. The electronic device of claim 1, wherein the seal is overmolded to the inner surface of the outer housing.

3. The electronic device of claim 1, wherein the enhanced sealing engagement between the seal and the support structures responsive to the pressure applied by the liquid is to prevent the liquid from flowing past the seal.

4. The electronic device of claim 1, wherein the seal is a first seal, the electronic device further comprising:
a connector assembly arranged adjacent an opening in the outer housing;
a communication cable extending from the connector assembly; and
a second seal engaged with communication cable to prevent liquid that has entered into the connector assembly from passing to an inner region of the electronic device.

5. The electronic device of claim 4, wherein the support structures comprise a connector support structure to support the connector assembly, wherein the second seal is engaged between the communication cable and the connector support structure, and the first seal is engaged between the outer housing and the connector support structure.

6. The electronic device of claim 1, further comprising:
a connector assembly arranged adjacent an opening in the outer housing, wherein the support structures comprise a connector support structure to support the connector assembly, wherein the seal is engaged between the outer housing and the connector support structure.

7. The electronic device of claim 1, wherein the seal comprises a first seal portion and a second seal portion that have an acute angle with respect to each other when facing a chamber into which liquid ingresses through a liquid ingress path of the outer housing.

8. The electronic device of claim 1, further comprising a display cover, wherein a gap exists between the display cover and the outer housing, the gap providing a liquid ingress path through which the liquid penetrates from outside the electronic device to the seal.

9. The electronic device of claim 1, further comprising:
a button assembly comprising a switch arranged in a pocket inside the outer housing; and
a depressible button to activate the switch,
wherein the switch includes a further seal arranged to sealingly engage a support structure for the button assembly to prevent a liquid from passing the switch into an inner region of the electronic device.

10. The electronic device of claim 9, wherein the further seal is overmolded onto the button circuit board.

11. A housing assembly for an electronic device comprising:
an outer housing;
an opening in the outer housing for a communication connector assembly of the electronic device;
a first seal that extends along a circumference along an inner surface of the housing, the seal engaged to the inner surface of the housing and to engage a support structure of the communication connector,
the first seal deflectable by the support structure upon engagement of the first seal with the support structure when the support structure is received in an inner chamber defined by the outer housing, and the first seal is positioned to enhance sealing engagement with the housing structures responsive to pressure applied by a liquid that has penetrated a portion of the outer housing; and
a second seal to engage a component of the communication connector assembly to prevent a liquid that has entered the communication connector assembly from passing to an inner region of the electronic device.

12. The housing assembly of claim 11, wherein the first seal is further deflectable by another support structure that supports a display panel of the electronic device.

13. The housing assembly of claim 11, wherein the first seal is overmolded onto the inner surface of the outer housing.

14. A method of forming a housing assembly for an electronic device, comprising:
molding a seal onto an inner surface of an outer housing, the seal extending along a circumference on the inner surface of the outer housing; and
arranging the seal be deflected by support structures for electronic components of the electronic device upon engagement of the seal with the support structures when the support structures are received in an inner chamber defined by the outer housing, the seal arranged to enhance sealing engagement with the support structures responsive to pressure applied by a liquid that has penetrated a portion of the outer housing.

15. The method of claim 14, wherein the seal is a primary seal, the method further comprising:
arranging a second seal that provides a fluid seal for a connector assembly or a button assembly positioned adjacent an opening of the outer housing, the opening providing access to the connector assembly or the button assembly.
